(19) United States
(12) Patent Application Publication
(10) Pub. No.: US 2009/0211730 A1
(43) Pub. Date: Aug. 27, 2009

(54) HEAT DISSIPATION DEVICE HAVING A BRACKET

(75) Inventors: SHI-WEN ZHOU, Shenzhen City (CN); SHOU-BIAO XU, Shenzhen City (CN); CHUN-CHI CHEN, Tu-Cheng (TW)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/143,846

(22) Filed: Jun. 23, 2008

(30) Foreign Application Priority Data
Feb. 22, 2008 (CN) 200810065409.6

(51) Int. Cl. H05K 7/20

(52) U.S. Cl. 165/80.3; 165/104.33

(57) ABSTRACT

A heat dissipation device includes a first heat sink, a second heat sink far away from the first heat sink, a heat pipe transferring heat from the first heat sink to the second heat sink and a bracket for reinforcing the heat dissipation device. The bracket includes a first end attached to the first heat sink and a second end attached to the second heat sink. The second end defines a through hole receiving the heat pipe therethrough. The second end has a supporting portion and a clasping portion from an edge of the through hole. The supporting portion and the clasping portion are spaced from each other and firmly clasp the heat pipe. The clasping portion is bent to abut against the heat pipe and urge the heat pipe toward the supporting portion.

### CROSS-REFERENCE TO RELATED APPLICATIONS

This application is related to U.S. patent application Ser. No. 11/308,250 filed on Mar. 14, 2006 and entitled “HEAT DISSIPATION DEVICE HAVING A BRACKET”, which is published as US Publication No. 2007/0215319 A1 on Sep. 20, 2007; the co-pending U.S. patent application is assigned to the same assignee as the instant application. The disclosure of the above-identified application is incorporated herein by reference.

### BACKGROUND OF THE INVENTION

1. Field of the Invention

The present invention generally relates to a heat dissipation device with two heat sinks interconnected by a heat pipe, and more particularly to such a heat dissipation device having a bracket to firmly support the heat pipe so that a separation of the heat pipe from the heat sinks can be avoided.

2. Description of Related Art

A conventional heat-pipe type heat dissipating device which is mounted onto an electronic component such as CPU and has two heat sinks connected together via a heat pipe is not sufficiently sturdy. The two heat sinks connect together only via the heat pipe. When an external force acts on the heat dissipation device, the heat pipe is likely to loosen from the heat sinks, thereby reducing the heat transfer performance of the heat pipe and thus also reducing the heat dissipating efficiency of the heat dissipation device. In addition, the loose heat pipe may produce noise during operation of the computer incorporating the heat dissipating device. An improved heat dissipation device having a bracket to enhance the sturdy of the device is proposed. US Publication No. 2007/0215319 A1 shows an example of this kind of heat dissipation device. The heat dissipation device includes a first heat sink, a second heat sink, a heat pipe conducting heat from the first heat sink to the second heat sink and a bracket connecting the first and second heat sink together. The bracket forms an annular flange to fix the heat pipe, thus enhancing the strength and stability of the heat dissipation device. However, a gap exists between the heat pipe and the annular flange of the bracket formed by an installation tolerance between the heat pipe and the annular flange, which leads to a possible relative movement between heat pipe and the bracket when the heat dissipation device is subject to vibration.

Accordingly, what is needed is a heat dissipation device having a bracket which can firmly and reliably fix a heat pipe to heat sinks thereof, thereby to improve the disadvantages confronted by the art.

### SUMMARY OF THE INVENTION

According to an embodiment of the present invention, a heat dissipation device includes a first heat sink, a second heat sink far away from the first heat sink, a heat pipe transferring heat from the first heat sink to the second heat sink and a bracket for reinforcing the heat dissipation device. The bracket includes a first end attached to the first heat sink and a second end attached to the second heat sink. The second end defines a through hole receiving the heat pipe therethrough. The second end has an arc-shaped supporting portion and a tab-shaped clasping portion from an edge of the through hole. The supporting portion and the clasping portion are spaced from each other, wherein the clasping portion is bent toward the heat pipe to urge the heat pipe toward the supporting portion; thus, the supporting portion and the clasping portion firmly clasp the heat pipe.

Other advantages and novel features will become more apparent from the following detailed description of preferred embodiment when taken in conjunction with the accompanying drawings.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views.

FIG. 1 is an exploded, isometric view of a heat dissipation device in accordance with a preferred embodiment of the present invention;

FIG. 2 is an assembled view of FIG. 1 before a clasping portion of a bracket is bent to clasp the heat pipe; and

FIG. 3 is an assembled view of FIG. 2 after the clasping portion of the bracket is bent to firmly clasp the heat pipe.

### DETAILED DESCRIPTION OF THE INVENTION

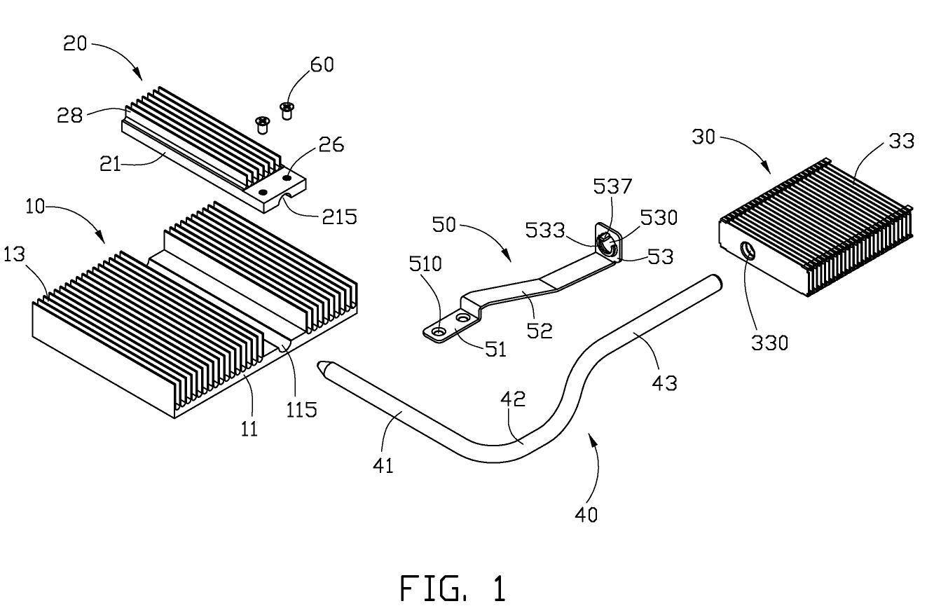

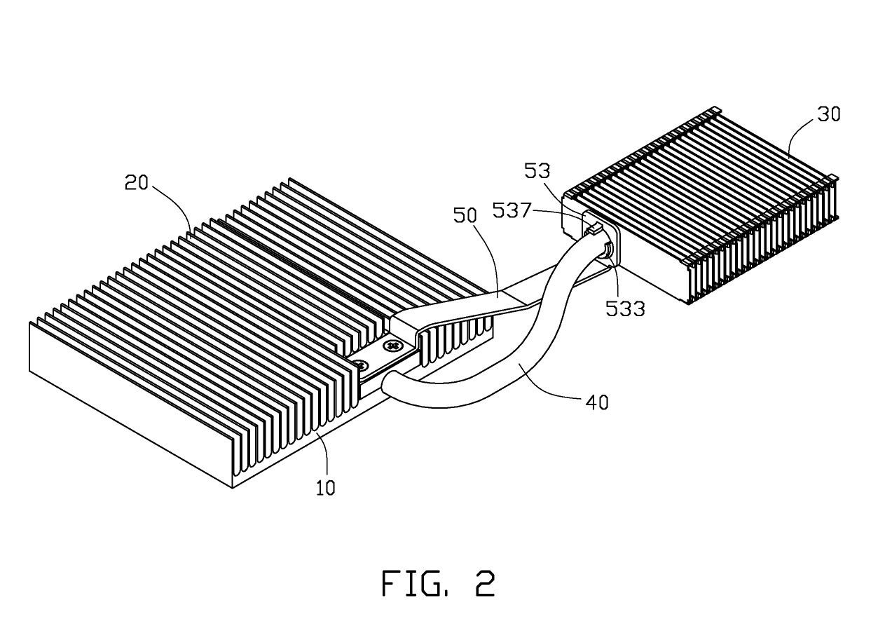

Referring to FIGS. 1-2, a heat dissipation device (not labeled) in accordance with a preferred embodiment of the present invention is shown. The heat dissipation device mainly comprises a first heat sink 70 for contacting a CPU (not shown), a second heat sink 30 far from the first heat sink 70 and a heat pipe 40 thermally and mechanically connecting the first heat sink 70 and the second heat sink 30 together. A bracket 50 mechanically connects the first heat sink 70, the heat pipe 40 and the second heat sink 30 together, so as to reinforce the whole structure of the heat dissipation device.

The first heat sink 70 comprises a base 10, two spaced groups of fins 13 extending upwardly from the base 10 and a mounting member 20 mounted between the two groups of fins 13. A connection area 18 of the base 10 is formed between the two groups of fins 13. A groove 115 is defined in the connection area 18 of the base 10 for receiving an evaporating portion 41 of the heat pipe 40. The mounting member 20 is mounted on the connection area 18 of the first heat sink 70. The mounting member 20 comprises a base 21 parallel to the base 10 and a plurality of fins 28 extending upwardly from the base 21 thereof. Each of the fins 28 is parallel to each of the fins 13 of the first heat sink 70. The base 21 of the mounting member 20 has a same length as the base 10 of the first heat sink 70 along front-to-rear direction. A length of the fins 28 is shorter than that of the base 21 such that a mating area 27 is formed at a top edge of the base 21. A pair of threaded holes 26 are defined in the mating area 27 of the base 21. A groove 215 corresponding to the groove 115 is defined in a bottom of the base 10. The groove 215 and the groove 115 cooperatively form a channel for receiving the evaporating portion 41 of the heat pipe 40.

The second heat sink 30 comprises a plurality of fins 33 spaced from and snapped with each other. The fins 33 are perpendicular to the base 10 of the first heat sink 70. A through hole 330 is laterally defined in the fins 33 for receiving a condensing portion 43 of the heat pipe 40.

The bracket 50 is formed by stamping a metal sheet. The bracket 50 comprises two free ends 51, 53 and a connecting arm 52 interconnecting the free ends 51, 53. The free end 51 parallel to the base 10 of the first heat sink 70 is mounted on the mating area 27 of the mounting member 20 of the first heat sink 70. The free end 53 parallel to the fins 33 of the second heat sink 30 is mounted on the second heat sink 30. The free end 51 defines a pair of mounting holes 510 corresponding to the threaded holes 26 of the mating area 27 of the first heat sink 70. The free end 53 is substantially perpendicular to the free end 51. The connecting arm 52 has a bend (not labeled) at a substantially central portion thereof.

The free end 53 defines a circular through hole 530 therein. An inner diameter of the through hole 530 of the free end 53 is slightly larger than an outer diameter of the heat pipe 40. An arced supporting portion 533 extends perpendicularly from a lower edge of the through hole 530. The supporting portion 533 has a length extending a three-quarter circle surrounding the through hole 530. A clasping portion 537 protrudes perpendicularly and outwardly from the edge of the through hole 530 and is located between two opposing ends of the supporting portion 533. The clasping portion 537 is spaced from the two opposing ends of the supporting portion 533. In this embodiment, the supporting portion 533 is located near the connecting arm 52 than the clasping portion 537. Two gaps (not labeled) are defined between the supporting portion 533 and the clasping portion 537. The clasping portion 537 is located at a top of the through hole 530.

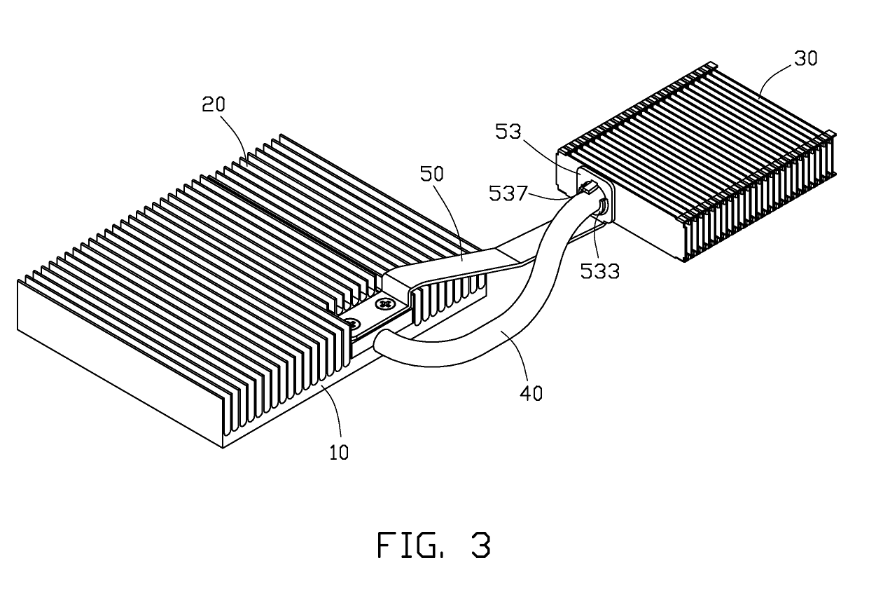

In assembly, the grooves 115, 215, the connection area 18, and an inner surface of the through hole 330 are coated with solder. The evaporating portion 41 of the heat pipe 40 is soldered into the channel of the first heat sink 70 formed by the grooves 115, 215. The free end 51 of the bracket 50 is positioned on the mating area 27 of the mounting member 20 of the first heat sink 70. A pair of screws 60 extend through the mounting holes 510 of the bracket 50 and screw into the threaded holes 26 of the first heat sink 70. The free end 53 of the bracket 50 abuts against a lateral side of an outmost fin 33 of the second heat sink 30 near the first heat sink 70 and the through hole 530 of the bracket 50 is aligned with the through hole 330 of the second heat sink 30. The condensing portion 43 of the heat pipe 40 is brought to extend in the through holes 330, 530 and is soldered in the through holes 530. Referring to FIG. 2 again, the clasping portion 537 and the supporting portion 533 are perpendicular to the free end 53 and located around an outer surface of the heat pipe 40. A small gap exists between the heat pipe 40 and the clasping portion 537 and the supporting portion 533 for assembling tolerance. Referring to FIG. 3, then, the clasping portion 537 is pressed downwardly to slantways abut against a top of the outer surface of the heat pipe 40. The clasping portion 537 urges the heat pipe 40 downwardly toward the supporting portion 533, whereby the small gap between the heat pipe 40 and the clasping portion 537 and the supporting portion 533 is no longer existed and the clasping portion 537 and the supporting portion 533 can securely clasp the condensation portion 43 of the heat pipe 40.

In used, the heat pipe 40 connecting with the first heat sink 70 and the second heat sink 30 is firmly mounted with the bracket 50. The bracket 50 shares a weight of the second heat sink 30 which is apart from the first heat sink 70. Simultaneously, because of the slantwise clasping portion 537 of the free end 53 of the bracket 50, the heat pipe 40 is reliably secured in position and immovable relative to the free end 53 of the bracket 50 even when the heat dissipation device is subject to vibration. In another embodiment, the free end 53 of the bracket 50 can have two or more clasping portions 537 for more easily and securely clasping the heat pipe 40.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a first heat sink;
a second heat sink;
a heat pipe interconnecting the first and second heat sinks and transferring heat from the first heat sink to the second heat sink; and
a bracket comprising a first end attached to the first heat sink and a second end attached to the second heat sink, for reinforcing the heat dissipation device, the second end defining a through hole receiving the heat pipe therethrough, the second end having a supporting portion and a clasping portion from an edge of the through hole, the supporting portion and the clasping portion being spaced from each other and firmly clasping the heat pipe.

2. The heat dissipation device as described in claim 1, wherein the supporting portion extends perpendicularly from the second end of the bracket, and the clasping portion is located between two opposing ends of the supporting portion.

3. The heat dissipation device as described in claim 2, wherein the clasping portion is spaced from the two opposing ends of the supporting portion.

4. The heat dissipation device as described in claim 3, wherein the through hole is circular.

5. The heat dissipation device as described in claim 4, wherein the supporting portion extends a three-quarter circle surrounding the through hole.

6. The heat dissipation device as described in claim 1, wherein the bracket comprises a connecting arm connecting the first end and the second end, and the supporting portion is located near the connecting arm than the clasping portion.

7. The heat dissipation device as described in claim 1, wherein the through hole of the second end has an inner diameter slightly larger than an outer diameter of the heat pipe.

8. The heat dissipation device as described in claim 1, wherein the bracket is formed by stamping a metal sheet.

9. A heat dissipation device comprising:
a first heat sink;
a second heat sink;
a heat pipe having a first end extending through the first heat sink and a second end extending through the second heat sink; and
a bracket comprising a first end attached to the first heat sink and a second end attached to the second heat sink to fix the second end of the heat pipe on the second heat sink, the second end defining a through hole for passage of the second end of the heat pipe therethrough, a supporting portion extending and outwardly from an edge of the through hole and forming two disconnected ends, a clasping portion formed from the edge of the through hole and located between the two disconnected ends of the supporting portion, the supporting portion and the clasping portion cooperatively clasping an outer surface of the heat pipe.

10. The heat dissipation device as described in claim 9, wherein the through hole is circular.

11. The heat dissipation device as described in claim 10, wherein the supporting portion extends a three-quarter circle surrounding the through hole.

12. The heat dissipation device as described in claim 9, wherein gaps exist between the clasping portion and the two disconnected ends of the supporting portion.

13. The heat dissipation device as described in claim 9, wherein the supporting portion has an arc-shaped configuration and the clasping portion has a tab-shaped configuration, the clasping portion abutting slantwise against the heat pipe and urging the heat pipe toward the supporting portion.
